(19) United States
(12) Patent Application Publication
(10) Pub. No.: US 2013/0318418 A1
(43) Pub. Date: Nov. 28, 2013

(54) ADAPTIVE ERROR CORRECTION FOR PHASE CHANGE MEMORY

(71) Applicants: Ferdinando Bedeschi, Biassono (MB) (IT); Roberto Gastaldi, Agrate Brianza (MB) (IT); Christophe Laurent, Agrate Brianza (MB) (IT); Paolo Amato, Pagazzano (BG) (IT); Sandro Bellini, Monza (MB) (IT); Alessandro Tomasoni, Lesmo (MB) (IT)

(72) Inventors: Ferdinando Bedeschi, Biassono (MB) (IT); Roberto Gastaldi, Agrate Brianza (MB) (IT); Christophe Laurent, Agrate Brianza (MB) (IT); Paolo Amato, Pagazzano (BG) (IT); Sandro Bellini, Monza (MB) (IT); Alessandro Tomasoni, Lesmo (MB) (IT)

(73) Assignees: Politecncio di Milano, Milan (IT); Micron Technology, Inc., Boise, ID (US)

(21) Appl. No.: 13/477,610

(22) Filed: May 22, 2012

(51) Int. Cl. H03M 13/03; G06F 11/10

(52) U.S. Cl. 714/758; 714/E11.032

(57) ABSTRACT

Subject matter disclosed herein relates to memory operations regarding error correction or error detection.

### BACKGROUND

1. Field

Subject matter disclosed herein relates to memory operations regarding error correction or error detection.

2. Information

Memory devices may be employed in various electronic devices, such as computers, cell phones, PDA's, data loggers, or navigational equipment, just to name a few examples. For example, various types of nonvolatile memory devices may be employed, such as solid state drives (SSD), NAND or NOR flash memory, or phase change memory (PCM), among others. In general, writing or programming operations may be used to store information, while read operations may be used to retrieve stored information. A write or read operation may involve one or more processes to detect or correct errors in information written to or read from memory.

Nonvolatile memory devices may comprise memory cells that slowly deteriorate over time, leading to an increasing probability that a read or write error may occur upon accessing such a memory cell. Errors may also result from manufacture defects or marginal memory device construction, just to name a few examples. Accordingly, an error correction process may be employed to correct such errors as they occur. For example, an error correction coding (ECC) engine may be employed in a memory device in order to correct errors generated in the memory device, though an ECC engine may be limited in its ability to correct errors.

### BRIEF DESCRIPTION OF THE FIGURES

Non-limiting and non-exhaustive embodiments will be described with reference to the following figures, wherein like reference numerals refer to like parts throughout the various figures unless otherwise specified.

FIG. 1 is a flow diagram of an embodiment of a process of applying error detection or correction to a portion of memory.

FIG. 2 is a flow diagram of another embodiment of a process of applying error detection or correction to a portion of memory.

FIG. 3 is a flow diagram of yet an embodiment of a process of applying error detection or correction to a portion of memory.

FIG. 4 is a plot of characteristics of latency versus bit error rate for a memory device, according to an embodiment.

FIG. 5 is a schematic diagram illustrating an embodiment of a computing system.

### DETAILED DESCRIPTION

Reference throughout this specification to “one embodiment” or “an embodiment” means that a particular feature, structure, or characteristic described in connection with an embodiment is included in at least one embodiment of claimed subject matter. Thus, appearances of phrases such as “in one embodiment” or “an embodiment” in various places throughout this specification are not necessarily all referring to the same embodiment. Furthermore, particular features, structures, or characteristics may be combined in one or more embodiments.

Embodiments described herein include processes or electronic architecture involving adjustable levels, techniques, or types of error correction used in a memory device or memory system. Other embodiments may involve adjustable or variable levels of read latency of a memory device. For example, read latency of a portion of a memory array may be changed to accommodate a change in level, technique, or type of error correction used for the memory array. In one implementation, read or write speed may be measured in terms of latency. Here, latency refers to a time lag between reading or writing a group of bits and correcting the group of bits, for example. Also, a process of operating a memory device may include replacing a non-functional portion of memory with a portion of spare memory so that the memory system may continue to operate without loss of memory capacity, as explained below.

An error correction process may use an error correction code (ECC) that supplements a group of bits (e.g., user data) with parity bits to store enough extra information for the group of bits to be reconstructed if one or more bits of the group of bits become corrupted (e.g., contains one or more erroneous bits). A group of bits supplemented with parity bits is called an ECC codeword.

There may be trade-offs between an ability to correct or detect errors in a memory and operating speed of the memory. For example, operating speed of a memory incorporating an ECC having ability to correct up to two errors per read or write operation may be substantially faster than operating speed of a memory incorporating an ECC having an ability to correct up to three errors per read or write operation. Accordingly, in an embodiment, one technique of error correction may be replaced with another technique of error correction as needed to correct errors. For example, an operation to read a portion of memory may involve an error correction technique having an ability to correct up to two errors per read operation. If more than two errors occur, however, then the portion of memory may be re-read in a reading operation using an error correction technique having an ability to correct more than two errors per read operation.

In one embodiment, a method of operating a memory device may include selecting a particular error correction technique during a process of reading from the memory device. Such a selection may be performed, for example, if reading from a portion of the memory device leads to detection of a number of errors. In a particular implementation, selecting a particular error correction technique may be performed based on bit error rate (BER) measured for a plurality of read operations. The extent to which read or write errors may be corrected may depend, at least in part, on the particular error correction technique used in a read or write operation. For example, a Reed-Solomon ECC technique may provide a higher level of correction (e.g., more bits corrected per read or write operation) than that of an exclusive-or (XOR) parity error correction technique. For another example, an error correction technique utilizing 32-bit parity correction codes may provide a higher level of correction than that of an error correction technique using 16-bit parity correction codes.

Adjusting from one error correction technique to another, which may be performed during read or write operations, may involve modifying a memory map to replace a non-functional portion of memory with spare memory, for example. As described below, spare memory may comprise memory cells of a memory system not initially recognized nor considered as part of a capacity of the memory system in terms of information storage.

A memory device may comprise memory cells that slowly deteriorate over time, which may lead to increased BER and/or an increased probability that one or more errors occurs while writing to or reading from the memory device. A memory device may also comprise defective or marginally functional memory cells as a result of their manufacture, for example. Errors may be corrected using ECC or other such algorithms. From a system perspective, a determination may be made as to whether or not to continue to utilize such error-prone cells. Such a determination may be based, at least in part, on a comparison of the number of occurring errors (e.g., BER) to an error threshold, which may be defined during a design stage of a memory device, for example. In one implementation, use of particular memory cells may be discontinued before the memory cells display an excess number of errors. In another implementation, use of particular memory cells may be discontinued if errors are read from the memory cells in more than one read operation. Discontinuing use of memory cells may be expressed as “retiring memory cells”. Spare regions of a memory system may replace such retired memory cells in a manner that maintains an overall memory system capacity. As indicated above, such “spare” regions of memory may comprise memory set aside to replace non-functional memory.

A process of retiring memory cells may include moving or transferring signals representative of information or bits stored in the to-be-retired memory cells to memory cells in a spare portion of a memory system. For example, such a spare portion of a memory system may include a physical location of the memory system not initially recognized or considered as part of the full capacity of the memory system in terms of information storage. A process of retiring memory cells may also include remapping an address of to-be-retired memory cells to correspond to an address of replacement memory cells in a new, spare portion of the memory system. Of course, such processes are merely examples, and claimed subject matter is not so limited.

Embodiments, such as those described above, may allow successful use of storage devices involving relatively less reliable technologies. For example, a chip or die previously considered unusable may be employed in solid state drives (SSD) using embodiments described herein. Also, performing techniques described herein may extend a lifetime of a storage device to that of a majority of its memory cells rather than a shorter life of a relatively few of its memory cells. For example, an entire SSD need not become non-functional merely as a result of failure of a relatively small portion of memory cells of the SSD. A memory die may comprise a discrete semiconductor chip that may comprise a portion of individual memory partitions that collectively make up a larger memory system, such as an SSD, for example. A system-level ECC engine, that is, an ECC engine deployed external to a memory die, for example, may provide error detection or correction to individual memory dice, partitions, or sectors. In particular, a system-level ECC engine may function across multiple memory dice, thereby providing error correction for signals representative of bits read from the multiple memory dice.

A particular technique to identify read errors may comprise comparing bits read from memory with and without using ECC in the reading process. In detail, a particular portion of memory may be read while incorporating an ECC. Next, the particular portion of memory may be re-read without applying ECC. A difference between bits read with ECC and bits read without ECC may indicate errors in the read bits.

In an embodiment, techniques for adjusting from one error correction technique to another or to replace non-functional portions of memory with spare memory may be performed using a non-volatile memory device comprising a plurality of integrated circuit (IC) memory chips. Some IC memory chips may comprise memory to store read/write bits while other IC memory chips may comprise spare memory. In one implementation, corresponding memory sectors of the IC memory chips may comprise a memory partition. The non-volatile memory device may also comprise a controller to adjust from a first technique of error correction to a second technique of error correction applied to the memory partition in response to determining a presence of a number of errors exceeding a threshold. The controller may be able to identify such errors by detecting a difference between bits read from the memory sector using ECC and bits read without using ECC, as mentioned above. A first technique of error correction may use a greater number of parity bits than that of a second technique of error correction. For example, a first technique of error correction may comprise Reed-Solomon ECC and a second technique of error correction may comprise even/odd parity error detection. For a particular example, based, at least in part, on an error correction ability of a code and a length of the codeword, parity bits may vary from a few parity bits, say one or two dozen bits for a relatively short codeword (e.g., 128 to 256 bits and including several errors), to hundreds of parity bits for relatively large codeword (e.g., 4096 bits and including dozens of errors). In another example, for BCH codes with error correction capability I designed in GF(2^{m}), a “maximal” codeword length may comprise 2^{m-1} bits and a number of parity bits may be m*t. Of course, such error correction techniques are merely examples, and claimed subject matter is not so limited.

In an embodiment, a method for correcting errors may comprise reading bits representing states of a portion of a memory device using a first technique of error correction, and using a second technique of error correction to re-read the bits in response to detecting errors in the read bits. Such a second technique may be used to produce corrected bits, for example. In one implementation, a second technique of error correction may use a greater number of parity bits than that of a first technique of error correction. In another implementation, using a second technique of error correction may be initiated in response to detecting a number of errors exceeding an error-correcting ability of the first technique. In yet another implementation, using a second technique of error correction may be initiated in response to determining that a temperature of the memory device exceeds a threshold temperature. For example, a temperature sensor comprising a thermocouple or other temperature-measuring device may be located in or near a memory device to measure temperatures of the memory device or an area surrounding the memory device. BER and/or a probability of errors occurring in a memory device may increase as a temperature of the memory device increases.

Accordingly, in response to detecting a temperature of a memory device exceeding a threshold temperature, a second technique of error correction may be selected to replace a first technique of error correction. In such a case, the second technique of error correction may be able to correct a greater number of errors in a read or write operation than that of the first technique. Such a second technique may be selected because a probability of errors occurring in a memory device may increase as a result of increasing temperature of the memory device. A first technique of error correction may be replaced with a second technique during a subsequent write-read operation of a refresh process, as described below, for example.

In one implementation, a second technique of error correction may use Reed-Solomon ECC and a first technique of error correction may use even/odd parity ECC. In another implementation, a second technique of error correction may use BCH8 ECC and a first technique of error correction may use BCH2 ECC. Of course, such error correction techniques are merely examples, and claimed subject matter is not so limited.

In one embodiment, a second technique of error correction to re-read memory may be performed during a process to refresh the memory device, as mentioned above. For example, states of memory cells of a memory device may be refreshed by re-writing program signals to the memory cells to maintain the states. Such a refresh process may be performed repeatedly from time to time, or many times per second, for example. In one implementation, bits corrected by a second technique of error correction may be written to a portion of a memory device during such a process of refreshing a state of a memory device. Subsequently, if bits read from the portion of the memory device again include errors, then a memory map may be modified to remove accessibility of the portion of the memory device. Repeat occurrence of bit errors may indicate faulty memory cells in the portion of the memory device. Accordingly, bits corrected again using a second technique of error correction may be re-written to a spare portion of the memory device. Such a re-writing process may be performed during another process to refresh the memory device, for example.

In an embodiment, an apparatus may comprise an ECC engine to detect or correct errors stored in a memory array during a first read operation. The apparatus may also comprise a controller to select a technique of error correction to be applied to the memory array during a second read operation based, at least in part, on a number of errors detected during the first read operation. As discussed above, the apparatus may further comprise a temperature sensor to measure a temperature of the memory array. The controller may be able to determine whether the temperature exceeds a threshold temperature. Exceeding such a threshold temperature may result in an increased probability of errors, for example. In one implementation, a controller may be able to initiate a process to refresh a memory array based, at least in part, on determining whether a temperature of the memory array exceeds a temperature. A memory array may comprise phase change memory, though claimed subject matter is not so limited. Of course, such an apparatus is merely an example, and claimed subject matter is not so limited.

In another embodiment, read latency of at least a portion of memory may change to accommodate a change in level, technique, or type of error correction used for the memory, for example. As discussed above, BER may vary during the life of a chip. For example, BER may vary in response to cycling, retention, and/or temperature of at least portions of a memory device. Accordingly, to account for variations in BER, for example, mean read latency may be adjusted.

In one example implementation, an error correction process having a target uncorrectable bit error rate (UBER) of about 10⁻²⁰, may involve soft error decoding and/or concatenated error coding. In soft decoding, for each level read in a memory, a measure of the reliability of the read level may be given to a decoder (e.g., in terms of error probability). Concatenated codes may comprise two or more successive encoding processes. At a decoder, error that may have been left by a first (inner) decoder may be recovered by a second (outer) decoder, for example An error correction process involving soft error decoding and/or concatenated error coding may have relatively high latency. However, an error correction process may involve a hierarchy of ECC, which may lead to a reduced latency averaged over a period of the lifetime of a memory device, for example.

In one implementation, a concatenated ECC solution may involve two codes called an inner code and an outer code. An inner code may comprise a relatively slow soft-decoded code (e.g., low density parity check (LDPC) or Turbo code), while an outer code may comprise a relatively fast hard-decoded code (e.g., BCH). In an embodiment, an ECC concatenation technique may involve a fast outer code for a read process while a slow inner code may be selectively performed. For example, a slow inner code may be selectively triggered to be performed in response to a BER or number of errors resulting from a read process using an outer code. Such an ECC concatenation technique may lead to a lower mean latency time since an outer code may be relatively fast and may be configured to work with a reduced correction capability. Of course, such error correction processes are merely examples, and claimed subject matter is not so limited.

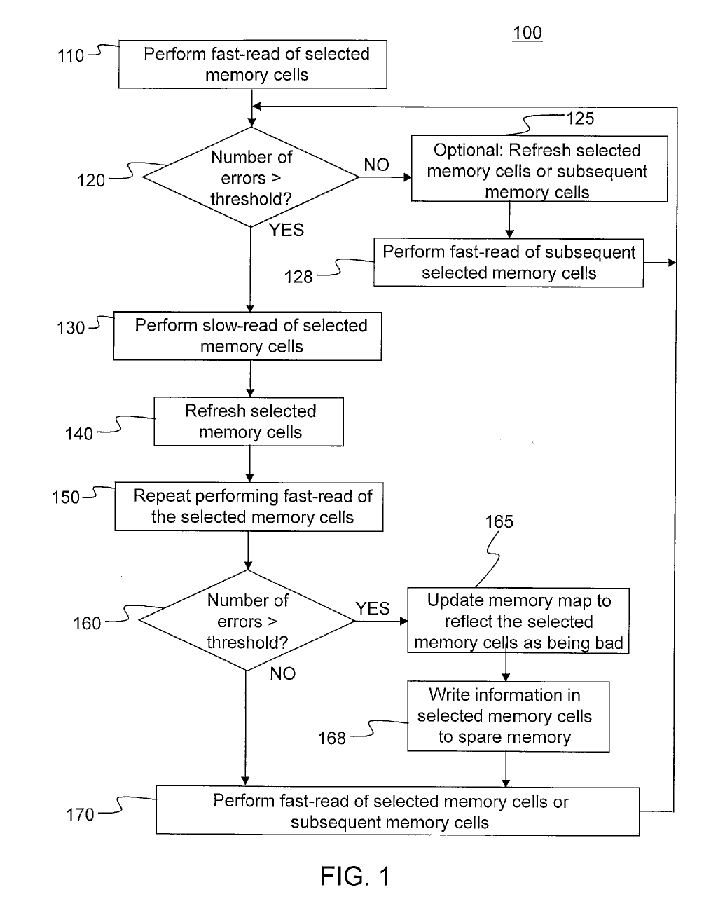

FIG. 1 is a flow diagram of an embodiment of a process 100 of using a process of error detection or correction to a portion of memory. At block 110, a process to perform a fast-read from memory cells may be initiated by a processor executing an application, for example. A “fast-read” comprises a read process that involves a first technique of error correction that may operate relatively fast compared to a “slow-read” comprising a second technique of error correction. For example, a relatively fast technique of error correction may lead to faster read or write operations compared to that of a relatively slow technique of error correction. Though a fast-read process may operate faster than a slow-read process, the fast-read process may have less capability of correcting errors compared to that of the slow-read process. At block 120, during a read process, an error correction process may detect or determine whether a number of errors exceeds a threshold of an ability of a first technique of error correction used in the fast-read to correct errors. In an implementation, memory locations (e.g., memory addresses) of detected errors may be logged or recorded in either a portion of the memory being written to or another memory, though claimed subject matter is not so limited. For example, a log of memory addresses where errors have been detected may be used later (e.g., as at block 165, described below) to determine whether memory cells corresponding to such memory addresses are relatively error-prone.

If a number of errors does not exceed a threshold of an ability of a first technique to correct errors, then process 100 may proceed to block 125 where, optionally, memory cells may be refreshed to maintain their respective states, as explained above. At block 128, a subsequent fast-read process may be performed in response to a processor executing an application, for example, or in response to a subsequent (and on-going) refresh process. In an alternate implementation, a subsequent fast-read process may be performed to check whether any new read process of the same location after a refresh pulse comprises a fast read, which may improve overall performance of memory system with time. Block 125 may be executed for a subsequent set of memory cells or for the same set of memory cells to measure and/or improve performance of the memory cells after a refresh pulse, for example. Process 100 may then return to block 120 where, during the subsequent fast-read process, an error correction process may detect or determine whether a number of errors exceeds a threshold of an ability for a first technique of error correction used in the fast-read to correct errors. If such a threshold is exceeded, then process 100 may proceed to block 130, where a slow-read process is performed, wherein the slow-read process may comprise a second technique of error correction that is able to correct a greater number of errors in a read or write operation than that of a fast-read comprising a first technique.

At block 140, memory cells may be refreshed to maintain their respective states, as explained above. At block 150, a subsequent fast-read process may be performed on at least some of the memory cells read at block 110 in response to a processor executing an application, for example, or in response to a subsequent (and on-going) refresh process. In an alternate implementation, a subsequent fast-read process may be performed to check whether any new read process of the same location after a refresh pulse comprises a passing fast read, which may improve overall performance of memory system with time. Process 100 may then proceed to block 160 where, during the subsequent fast-read process, an error correction process may detect or determine whether a number of errors in read bits exceeds a threshold of an ability for a first technique of error correction used in the fast-read to correct the errors in the read bits. For example, a determination may be made as to whether a number of errors read bits is beyond a capability of a fast-read process to correct, and in such a case the fast-read process may be replaced by a slow-read process, as at block 130. However, a determination may be made as to whether a portion of memory is faulty or non-functional. A portion of memory that is non-functional or producing too many errors may be retired or replaced with replacement memory comprising a portion of spare memory, as explained above. As a result, via a technique of remapping, subsequent write or read operations directed to the retired portion of memory may be re-directed to the replacement memory. For example, remapping may comprise assigning a new address to correspond, via a vector for example, to an original address so that the write request directed to the original address may be redirected to a new address specifying the location where bits are to be written. Also, bits stored in the retired portion of memory may be copied into the replacement memory.

Accordingly, if a number of errors again exceeds a threshold of an ability for a first technique of error correction used in the fast-read to correct errors, then process 100 may proceed to block 165: Repeatedly exceeding such a threshold for particular memory cells may indicate that such memory cells may be faulty. In other words, for example, particular memory cells may be re-read using a slow-read in response to exceeding such a threshold once. But if such a threshold is exceeded again, then the particular memory cells may be considered faulty and therefore replaced, as at block 165. As described above, replacing memory cells may involve updating a memory map and, as at block 168, writing bits stored in the replaced memory into spare memory. Process 100 may then proceed to block 170 where a subsequent fast-read process may be performed in response to a processor executing an application, for example, or in response to a subsequent (and on-going) refresh process. Process 100 may then return to block 120 where, during the subsequent fast-read process, an error correction process may detect or determine whether a number of errors exceeds a threshold of an ability for a first technique of error correction used in the fast-read to correct errors. Thus, process 100 may repeat, as described above. Also, subsequent to determining at block 160 that a number of errors does not exceed a threshold, process 100 may also proceed to block 170, and so on. Block 170 may be executed for a subsequent set of memory cells or to the same set of memory cells to measure and/or improve performance of the memory cells after a refresh pulse, for example. Of course, details of process 100 are merely examples, and claimed subject matter is not so limited.

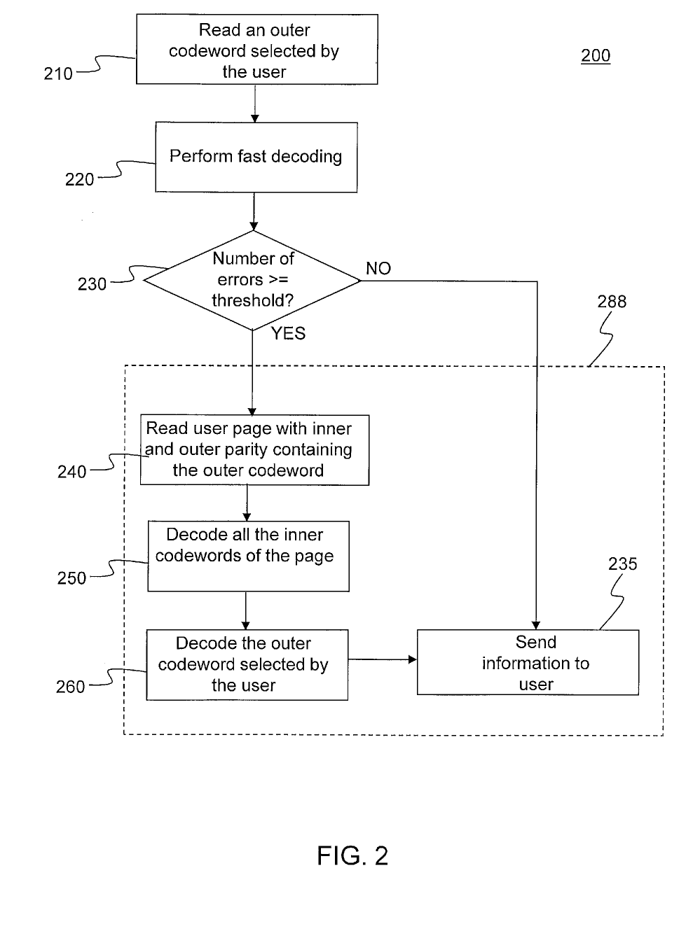

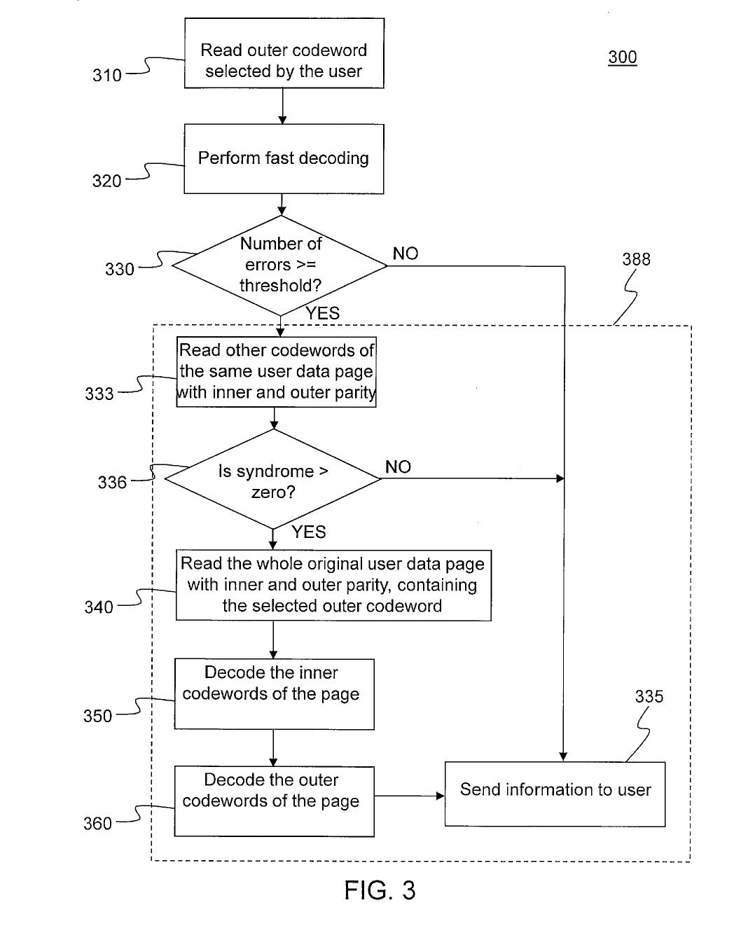

Some error correction techniques may involve serial concatenation of two ECCs. For example, processes 200 and/or 300 shown in FIGS. 2 and 3 and described below, may involve such techniques, though claimed subject matter is not so limited. In one implementation, a serial concatenation process may comprise adding parity check bits to user data during a write operation. Inner code may be used to add parity check bits of a whole inner codeword (e.g., user data+parity check bits). During read operation, inner code may be the first code to act whereas outer code may subsequently process output of the inner code, for example. Inner code may comprise a relatively slow soft-decoded code (e.g., LDPC or Turbo code), while outer code may comprise a relatively fast hard-decoded code (e.g., BCH).

In processes 200 and/or 300 shown in FIGS. 2 and 3 and described below, a user data page may be logically arranged in a matrix (irrespective of physical arrangement of a memory array, for example). A row of such a matrix may comprise a codeword of an outer code, while a column may comprise a codeword of an inner code. In one implementation, an outer code codeword may comprise a minimum size of information requested by a user, while a page of bits may comprise a word line of a memory device, for example.

FIG. 2 is a flow diagram of an embodiment of a process 200 of applying error detection or correction to a portion of memory. In a process such as 200, outer code need not be utilized at its “full” correction capability, but instead may be utilized at a relatively reduced correction capability. Accordingly, a determination may be made as to whether inner code is needed. Upon executing inner code, outer code may also be executed at its “full” correction capability.

At block 210, a process to read an outer codeword may be initiated by a processor executing an application, for example. An outer codeword may be selected by a user, though claimed subject matter is not so limited. An outer codeword may comprise a relatively fast hard-decoded code (e.g., BCH). At block 220, fast decoding may be performed by the processor, for example. Fast decoding may comprise applying an outer code (with restricted correction capability) to a codeword that includes relatively reduced information. On the other hand, accurate decoding may comprise applying a concatenation scheme to a whole page of information. For example, in a matrix arrangement, such as that described above, inner and outer codewords may be interleaved (e.g., an outer codeword need not be a subset of an inner codeword). Thus, a whole page of information may be read and/or processed (at least by an inner code, for example) before applying accurate decoding to a single outer codeword.

An outer code may be responsible for applying accurate decoding. For example, an outer code may comprise a BCH code that is able to correct t errors and detect at least 2 t errors. Let c (with c<t) be a restricted correction capability. During a read operation, fast decoding may be initiated (e.g., BCH with correction capability restricted to c). If in a read codeword the number of identified errors is less than or equal to c, the read codeword may be corrected, otherwise accurate decoding may be invoked. By choosing a suitable couple of values for t and c it may be possible to perform fast decoding with a probability of failed detection smaller that a target UBER.

At diamond 230, a determination may be made as to whether a number of detected errors is greater than or equal to a threshold. If not then process 200 may proceed to block 235 where requested read information, which may be corrected, may be provided to a user. However, if a number of detected errors is greater than or equal to a threshold, then process 200 may proceed to block 240 where a whole page of information, which may include inner and/or outer parity, may be read. The page of information may include a selected outer codeword, for example. At block 250, inner codewords of the page of information may be decoded. At block 260, an outer codeword selected by a user, for example, may be decoded. Information provided by process 200 at block 260 may be provided to a user at block 235.

Block 288 delineates activities that may be performed by a controller external to a memory die, in one implementation. For example, such a memory controller may be located external to a die that includes a memory array used in process 200. In another implementation, blocks 240, 250, 260, and/or 235 need not be performed by an external controller, and claimed subject matter is not limited in this respect. Of course, such details of process 200 are merely examples, and claimed subject matter is not so limited.

FIG. 3 is a flow diagram of yet an embodiment of a process of applying error detection or correction to a portion of memory. At block 310, a process to read an outer codeword may be initiated by a processor executing an application, for example. An outer codeword may be selected by a user, though claimed subject matter is not so limited. As discussed above, an outer codeword may comprise a relatively fast hard-decoded code, for example. At block 320, fast decoding may be performed by the processor, for example. Fast decoding may comprise applying an outer code to a codeword that includes relatively reduced information, while accurate decoding may comprise applying a concatenation scheme to a whole page of information, for example. At diamond 330, a determination may be made as to whether a number of detected errors is greater than or equal to a threshold. If not then process 300 may proceed to block 335 where requested read information may be provided to a user. However, if a number of detected errors is greater than or equal to a threshold, then process 300 may proceed to block 333 where codewords other than outer codewords may be read. In one implementation, such other codewords may include inner and/or outer parity and may comprise a portion of a page that includes outer codewords read in block 310, for example. At diamond 336, a determination may be made as to whether a syndrome is greater than zero. If not then process 300 may proceed to block 335 where requested read information may be provided to a user. However, if syndrome is greater than zero, then process 300 may proceed to block 340 where a whole page of information, which may include inner and/or outer parity, may be read. The page of information may include a selected outer codeword, for example. At block 350, inner codewords of the page of information may be decoded. At block 360, an outer codeword selected by a user, for example, may be decoded. Information provided by process 300 at block 360 may be provided to a user at block 335.

Block 388 delineates activities that may be performed by a controller external to a memory die, in one implementation. For example, such a memory controller may be located external to a die that includes a memory array used in process 300. In another implementation, blocks 333, 336, 340, 350, 360, and/or 335 need not be performed by an external controller, and claimed subject matter is not limited in this respect. Of course, such details of process 300 are merely examples, and claimed subject matter is not so limited.

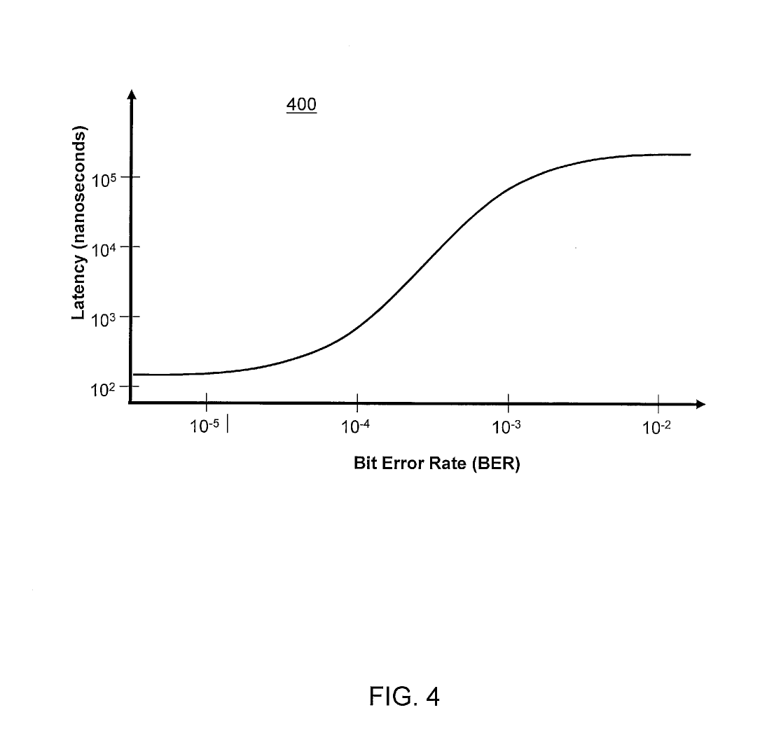

FIG. 4 is a plot 400 of characteristics of latency versus bit error rate for a memory device, according to an embodiment. Mean latency time may change as function of BER. In a particular example, if raw BER of a memory device increases from 10⁻⁵ to 10⁻² linearly with time, an average over the entire life of the memory device may be about 30 microseconds. In more detail, for example, accurate decoding (AD) (e.g., BCH8+LDPC) may be designed to cope with a “worst” case scenario that includes BER=1%. At the beginning of life of the memory device, BER may be about 10⁻⁵. In such a case, a BCH that is restricted to correct two errors may invoke AD once per million reads, for example. Consequently, although AD may span a time of about 150 microseconds, the mean latency time may be almost equal to the latency of fast decoding (FD): 200.15 nanoseconds versus 200 nanoseconds. On the other hand, if the memory device is near its end of life, AD may be invoked for almost all reads. Consequently, the mean latency time may be about 150 microseconds.

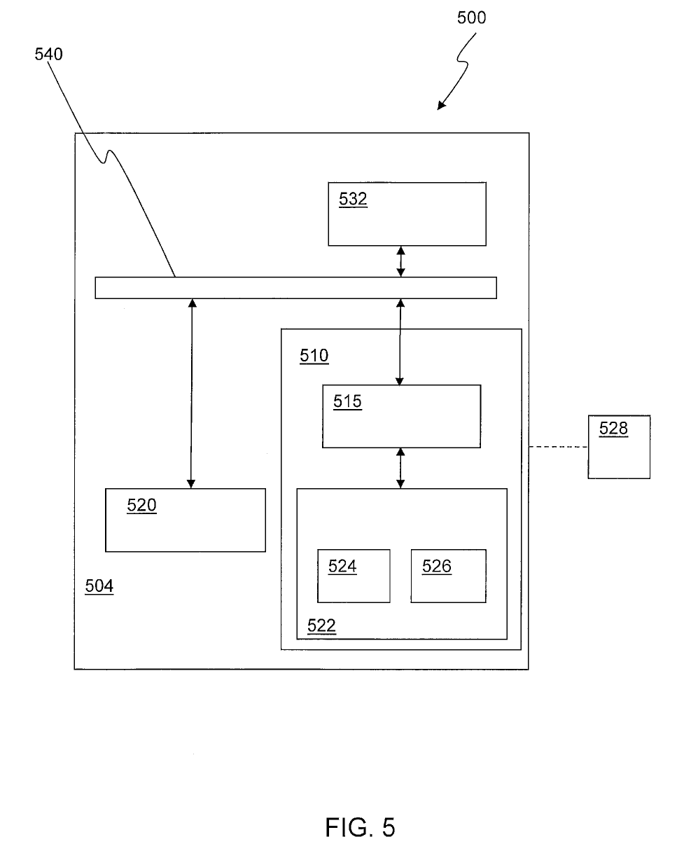

FIG. 5 is a schematic diagram illustrating an embodiment of a computing system 500 including a memory device 510. Such a computing device may comprise one or more processors, for example, to execute an application or other code. A computing device 504 may be representative of any device, appliance, or machine that may be configurable to manage memory device 510. Memory device 510 may include a memory controller 515 and a memory 522. By way of example but not limitation, computing device 504 may include: one or more computing devices or platforms, such as, e.g., a desktop computer, a laptop computer, a workstation, a server device, or the like; one or more personal computing or communication devices or appliances, such as, e.g., a personal digital assistant, mobile communication device, or the like; a computing system or associated service provider capability, such as, e.g., a database or information storage service provider/system; or any combination thereof.

It is recognized that all or part of the various devices shown in system 500, and the processes and methods as further described herein, may be implemented using or otherwise including hardware, firmware, software, or any combination thereof. Thus, by way of example but not limitation, computing device 504 may include at least one processing unit 520 that is operatively coupled to memory 522 through a bus 540 and a host or memory controller 515. Processing unit 520 is representative of one or more circuits configurable to perform at least a portion of an information computing procedure or process. By way of example but not limitation, processing unit 520 may include one or more processors, controllers, microprocessors, microcontrollers, application specific integrated circuits, digital signal processors, programmable logic devices, field programmable gate arrays, and the like, or any combination thereof. Processing unit 520 may include an operating system configured to communicate with memory controller 515. Such an operating system may, for example, generate commands to be sent to memory controller 515 over bus 540. Such commands may comprise read or write commands. In response to a write command, for example, memory controller 515 may adjust a level of correction of memory 522 to extend the life of a device that comprises the memory if a portion of the memory is determined to be non-functional.

In one implementation, memory 522 may comprise a portion of memory to store bits provided by one or more applications and a spare memory portion to store bits corrected by an ECC process. Memory controller 515, which may comprise an ECC engine, may selectively apply different techniques of error correction to the portion of memory for sequential read operations to read from the portion of memory. In another implementation, an ECC engine may be located outside memory device 510. For example, processing unit 520 may comprise an ECC engine, though claimed subject matter is not so limited. As described above, such a memory controller may be able to remap memory locations in the portion of memory that are determined to be non-functional to the spare memory portion. In one example, memory controller 515 may be able to adjust a frequency of refresh operations to refresh the portion of memory. Of course, such details of memory 522 are merely examples, and claimed subject matter is not so limited.

In a particular implementation, computing system 500 may comprise memory 522 comprising a first number of memory sectors to store information provided by one or more applications and a second number of memory sectors to store ECC associated with the information. Memory 522 may further comprise memory controller 515 to adjust from a first level of error correction to a second level of error correction applied to the memory in response to determining that at least a portion of the memory is non-functional.

Memory 522 is representative of any information storage mechanism. Memory 522 may include, for example, a primary memory 524 or a secondary memory 526. Primary memory 524 may include, for example, a random access memory, read only memory, etc. While illustrated in this example as being separate from processing unit 520, it should be understood that all or part of primary memory 524 may be provided within or otherwise co-located/coupled with processing unit 520.

Secondary memory 526 may include, for example, the same or similar type of memory as primary memory or one or more information storage devices or systems, such as, for example, a disk drive, an optical disc drive, a tape drive, a solid state memory drive, etc. In certain implementations, secondary memory 526 may be operatively receptive of, or otherwise configurable to couple to, a computer-readable medium 528. Computer-readable medium 528 may include, for example, any medium that can carry or make accessible information, code, or instructions for one or more of the devices in system 500.

Computing device 504 may include, for example, an input/output 532. Input/output 532 is representative of one or more devices or features that may be configurable to accept or otherwise introduce human or machine inputs, or one or more devices or features that may be configurable to deliver or otherwise provide for human or machine outputs. By way of example but not limitation, input/output device 532 may include an operatively configured display, speaker, keyboard, mouse, trackball, touch screen, data port, etc.

It will, of course, be understood that, although particular embodiments have just been described, claimed subject matter is not limited in scope to a particular embodiment or implementation. For example, one embodiment may be in hardware, such as implemented on a device or combination of devices, for example. Likewise, although claimed subject matter is not limited in scope in this respect, one embodiment may comprise one or more articles, such as a storage medium or storage media that may have stored thereon instructions capable of being executed by a specific or special purpose system or apparatus, for example, to result in performance of an embodiment of a method in accordance with claimed subject matter, such as one of the embodiments previously described, for example. However, claimed subject matter is, of course, not limited to one of the embodiments described necessarily. Furthermore, a specific or special purpose computing platform may include one or more processing units or processors, one or more input/output devices, such as a display, a keyboard or a mouse, or one or more memories, such as static random access memory, dynamic random access memory, flash memory, or a hard drive, although, again, claimed subject matter is not limited in scope to this example.

The terms, “and” and “or” as used herein may include a variety of meanings that will depend at least in part upon the context in which it is used. Typically, “or” if used to associate a list, such as A, B or C, is intended to mean A, B, and C, here used in the inclusive sense, as well as A, B or C, here used in the exclusive sense. Embodiments described herein may include machines, devices, engines, or apparatuses that operate using digital signals. Such signals may comprise electronic signals, optical signals, electromagnetic signals, or any form of energy that provides information between locations.

In the preceding description, various aspects of claimed subject matter have been described. For purposes of explanation, specific numbers, systems, or configurations may have been set forth to provide a thorough understanding of claimed subject matter. However, it should be apparent to one skilled in the art having the benefit of this disclosure that claimed subject matter may be practiced without those specific details. In other instances, features that would be understood by one of ordinary skill were omitted or simplified so as not to obscure claimed subject matter. While certain features have been illustrated or described herein, many modifications, substitutions, changes, or equivalents may now occur to those skilled in the art. It is, therefore, to be understood that the appended claims are intended to cover all such modifications or changes as fall within the true spirit of claimed subject matter.

What is claimed is:

1. A method comprising:
reading bits representing at least one state of a portion of a memory device using a first technique of error correction; and
using a second technique of error correction to re-read bits in response to detecting errors in said read bits to produce corrected bits.

2. The method of claim 1, wherein said second technique of error correction uses a greater number of parity bits than that of said first technique of error correction.

3. The method of claim 1, further comprising:
writing said corrected bits to said portion of said memory device during a process to refresh said memory device.

4. The method of claim 3, further comprising:
further reading said portion of said memory device subsequent to said writing said corrected bits to said portion of said memory device; and
modifying a memory map to remove accessibility of said portion of said memory device in response to detecting errors in said further read bits.

5. The method of claim 4, further comprising:
rewriting said corrected bits to a spare portion of said memory device in response to said detecting errors in said further read bits.

6. The method of claim 5, wherein said rewriting said corrected bits to said spare portion of said memory device is performed during another process to refresh said memory device.

7. The method of claim 1, wherein said using said second technique of error correction further comprises using said second technique of error correction in response to a number of said detected errors exceeding an error-correcting capability of said first technique of error correction.

8. The method of claim 1, wherein said using said second technique of error correction further comprises using said second technique of error correction in response to a measured temperature of said memory device exceeding a threshold temperature.

9. The method of claim 1, wherein said second technique of error correction uses Reed-Solomon error correction code (ECC) and said first technique of error correction uses even/odd parity ECC.

10. The method of claim 1, wherein said second technique of error correction uses BCH8 ECC and said first technique of error correction uses BCH2 ECC.

11. The method of claim 1, wherein detecting said errors in said read bits further comprises detecting a difference between bits read from said portion of said memory using ECC and bits read from said portion of said memory without using ECC.

12. An apparatus comprising:
an error correction code (ECC) engine to detect or correct errors stored in a memory array during a first read operation; and
a controller to select an error correction technique to apply to said memory array during a second read operation based, at least in part, on a number of errors detected during said first read operation.

13. The apparatus of claim 12, further comprising:
a temperature sensor to measure a temperature of said memory array, wherein said controller is able to determine whether said measured temperature exceeds a threshold temperature.

14. The apparatus of claim 13, wherein said controller is capable of initiating a process to refresh said memory array based, at least in part, on said determining whether said measured temperature exceeds said threshold temperature.

15. The apparatus of claim 12, further comprising:
a spare portion of said memory array to receive corrected hits comprising previously erroneous bits stored in said memory array corrected by said selected error correction technique during said second read operation.

16. A system comprising:
memory comprising a portion of memory to store bits provided by one or more applications and a spare memory portion to store bits corrected using an error correction code (ECC), said memory further comprising a memory controller to:
selectively apply different techniques of error correction to said portion of memory for sequential read operations to read from said portion of memory; and
a processor to host said one or more applications and to initiate said read operations to said memory controller.

17. The system of claim 16, wherein said memory controller is capable of remapping memory locations in said portion of memory that are determined to be non-functional to said spare memory portion.

18. The system of claim 16, wherein said memory controller is able to adjust a frequency of refresh operations to refresh said portion of memory.

19. The system of claim 16, wherein said different techniques of error correction use different sizes of ECC.

20. A method of correcting errors in a memory device comprising:
reading bits from a memory portion using a first technique of error correction; and
re-reading said memory portion using a second technique of error correction if a measured temperature of said memory device exceeds a threshold temperature.
